(19) United States
(12) Patent Application Publication
(10) Pub. No.: US 2016/0163624 A1
(43) Pub. Date: Jun. 9, 2016

(54) PACKAGE STRUCTURE

(71) Applicant: Powertech Technology Inc., Hsinchu County (TW)

(72) Inventor: Wen-Jeng Fan, Hsinchu County (TW)

(21) Appl. No.: 14/564,091

(22) Filed: Dec. 9, 2014

(51) Int. Cl. H01L 23/498; H01L 23/31; H01L 23/00

(52) U.S. Cl. CPC H01L 23/49811; H01L 24/09; H01L 24/32; H01L 23/49822; H01L 23/3128; H01L 2224/04042

(57) ABSTRACT

A package structure includes a chip, a substrate, wires and a molding compound. The chip includes an active surface, a back surface opposite to the active surface and bonding pads disposed on the active surface. The substrate includes a first solder mask, a first patterned circuit layer and a core layer having a first surface and a second surface opposite to the first surface. The first patterned circuit layer is disposed on the first surface. The first solder mask disposed on the first surface partially exposes the first patterned circuit layer. The substrate disposed on the active surface with the second surface exposes the bonding pads. The wires are connected between the first patterned circuit layer and the bonding pads. The molding compound covers the chip, the wire and the substrate. A top surface of the molding compound is coplanar with a top surface of the first solder mask.

### BACKGROUND OF THE INVENTION

1. Field of the Invention

The present invention generally relates to a package structure. More particularly, the present invention relates to a package structure of a chip.

2. Description of Related Art

Along with the rapid development of technologies, integrated circuit (IC) devices have been broadly applied in various aspects of our daily life. Generally speaking, the fabrication of an IC is divided into three phases: the fabrication of silicon wafer, the fabrication of the IC, and the packaging of the IC. Modern electronic equipment relies heavily on printed circuit boards on which semiconductor chips, or integrated circuits (ICs), are mounted. The mechanical and electrical connections between the IC and the substrate have posed challenges for chip designers. Wire bonding is one of the well known techniques for interconnecting the IC to the substrate.

In general, wire bonding technique refers to bonding from an IC to a substrate. A wire bonding process places a ball bond on the die first, a capillary then forms a stitch bond from the ball bond to a pad of the substrate. However, the typical wire bonding has a loop height constraint due to the neck area above the ball. Excessive bending above the ball can cause neck cracks, which results in reliability problems. Accordingly, the molding compound has to cover the entire loop to protect the electrical connection between the IC to the substrate, which makes the thickness of the package structure hard to be further reduced. Therefore, the package structure using wire bonding process is hard to meet the requirements of low-profile looping.

### SUMMARY OF THE INVENTION

Accordingly, the present invention is directed to a package structure which meets the low-profile requirements.

The present invention provides a package structure includes at least one chip, at least one substrate, a plurality of wires and a molding compound. The chip includes a plurality of bonding pads, an active surface and a back surface opposite to the active surface. The bonding pads are disposed on the active surface. The substrate includes a first solder mask, a first patterned circuit layer and a core layer. The core layer has a first surface and a second surface opposite to the first surface. The first patterned circuit layer is disposed on the first surface, the first solder mask is disposed on the first surface and partially exposing the first patterned circuit layer, and the substrate is disposed on the active surface with the second surface and exposes the bonding pads. The wires are connected between the first patterned circuit layer and the bonding pads. The molding compound covers the chip, the wire and the substrate. A top surface of the molding compound is coplanar with a top surface of the first solder mask.

According to an embodiment of the present invention, the package structure further includes a plurality of solder balls disposed on the first surface and electrically connected to the first patterned circuit layer exposed by the first solder mask.

According to an embodiment of the present invention, the package structure further includes a carrier. The chip is disposed on the carrier with the back surface.

According to an embodiment of the present invention, the package structure further includes an adhesive disposed between the chip and the carrier.

According to an embodiment of the present invention, a loop height is from a point of one of the wires connecting to the first patterned circuit layer to a highest point of the one of the wires farthest from the active surface. The thickness of the first solder mask is greater than the loop height.

According to an embodiment of the present invention, wherein the thickness of the first solder mask is greater than 30 μm.

According to an embodiment of the present invention, the substrate further includes a second patterned circuit layer and a plurality of conductive vias. The second patterned circuit layer is disposed on the second surface, and the conductive vias penetrates the substrate and connects between the first patterned circuit layer and the second patterned circuit layer.

According to an embodiment of the present invention, the substrate further includes a second solder mask disposed on the second surface of the substrate and covers the second patterned circuit layer, and the substrate is disposed on the active surface with second solder mask.

According to an embodiment of the present invention, the package structure further includes an adhesive, disposed between the substrate and the chip.

According to an embodiment of the present invention, a size of the chip is greater than a size of the substrate.

According to an embodiment of the present invention, wherein the number of the at least one chip is plural and the number of the at least one substrate is plural. Each of the substrate is disposed on the active surface of the corresponding chip and exposes the corresponding bonding pads.

According to an embodiment of the present invention, the wires are connected between the first patterned circuit layer of each substrate and the bonding pads of the corresponding chip.

According to an embodiment of the present invention, the package structure further includes a carrier. The chips are disposed on the carrier with the back surfaces.

According to an embodiment of the present invention, wherein the package structure further includes an adhesive disposed between the chips and the carrier.

Based on the above-mentioned description, in the package structure of the present invention, the substrate is disposed on the chip and exposes the bonding pads of the chip. The wire is connected between the first patterned circuit layer of the substrate and the bonding pad of the chip. Accordingly, the thickness of the first solder mask covering the first patterned circuit layer is greater than the loop height of the wire from the first patterned circuit layer, and the top surface of the molding compound is coplanar with the top surface of the first solder mask to cover the entire wire loop, so the wire loop would not give additional thickness to the package structure. Therefore, the overall thickness of the package structure can be reduced, so as to meet the requirements of low-profile package structure.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a chip package according to an embodiment of the invention.

FIG. 2 is a cross-sectional view of a chip package according to another embodiment of the invention.

FIG. 3 is a cross-sectional view of a chip package according to another embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. It is to be understood that the phraseology and terminology used herein are for the purpose of description and should not be regarded as limiting. The use of “including,” “comprising,” or “having,” and variations thereof herein is meant to encompass the items listed thereafter and equivalents thereof as well as additional items. On the other hand, the drawings are only schematic and the sizes of components may be exaggerated for clarity. It is to be understood that other embodiments may be utilized and structural changes may be made without departing from the scope of the invention. Unless limited otherwise, the terms “connected,” “coupled,” and “mounted,” and variations thereof herein are used broadly and encompass direct and indirect connections, couplings, and mountings. Accordingly, the drawings and descriptions will be regarded as illustrative in nature and not as restrictive.

Reference will now be made in detail to the present preferred embodiments of the invention, examples of which are illustrated in the accompanying drawings. Wherever possible, the same reference numbers are used in the drawings and the description to refer to the same or like parts.

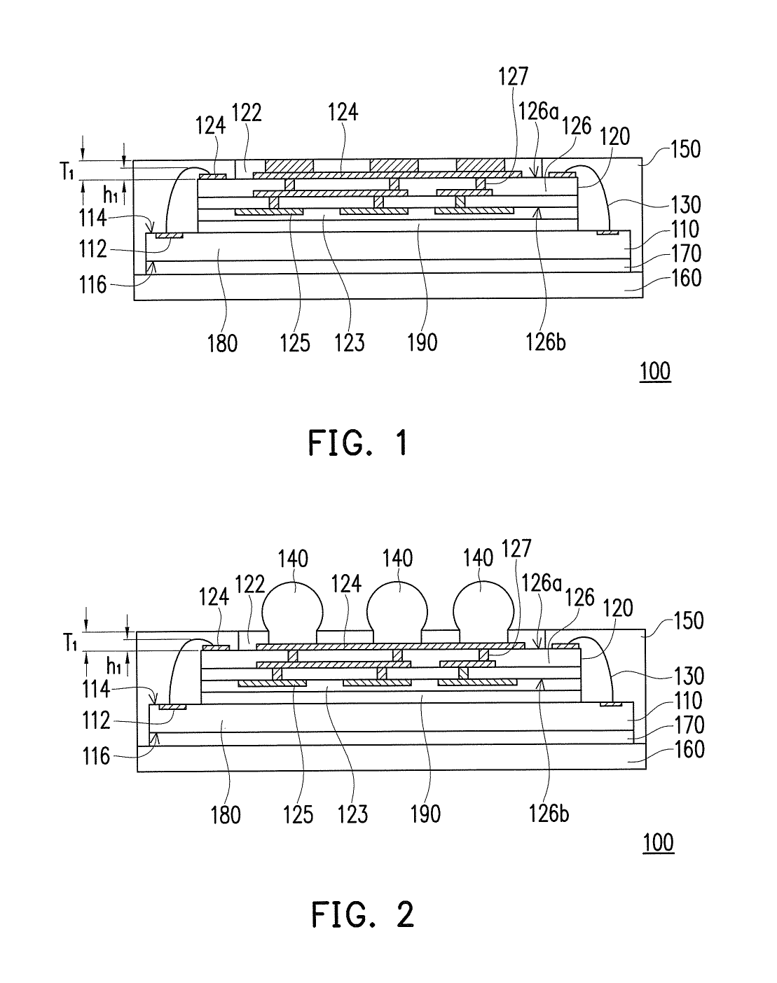

FIG. 1 is a cross-sectional view of a chip package according to an embodiment of the invention. Referring to FIG. 1, in the present embodiment, a package structure 100 includes at least one chip 110, at least one substrate 120, a plurality of wires 130 and a molding compound 150. In the present embodiment, the package structure 100 includes one chip 110 and one substrate 120, but the invention is not limited thereto. The chip 110 includes a plurality of bonding pads 112, an active surface 114 and a back surface 116 opposite to the active surface 114. The bonding pads 112 are disposed on the active surface 114. The substrate 120 includes a first solder mask 122, a second solder mask 123, a first patterned circuit layer 124, a second patterned circuit layer 125, a core layer 126 and a plurality of conductive vias 127. The core layer 126 has a first surface 126a and a second surface 126b opposite to the first surface 126a. The first patterned circuit layer 124 is disposed on the first surface 126a, and the second patterned circuit layer 125 is disposed on the second surface 126b. The conductive vias 127 are configured for electrically connecting the first patterned circuit layer 124 and the second patterned circuit layer 125. The substrate 120 may be a single layer board or a multi-layer board. In the present embodiment, the substrate 120 is a multi-layer board as shown in FIG. 1, and the substrate 120 may includes more than just the first patterned circuit layer 124 and the second patterned circuit layer 125 but also other patterned circuit layers in between. As such, the conductive vias 127 are configured for connecting between the patterned circuit layers so as to electrically connect the first patterned circuit layer 124 and the second patterned circuit layer 125. The first patterned circuit layer 124 and the second patterned circuit layer 125 may be formed by build-up process, subtractive process, or semi-additive process. The invention is not limited thereto.

Accordingly, the first solder mask 122 is disposed on the first surface 126a and partially exposing the first patterned circuit layer 124, while the second solder mask 126 is disposed on the second surface 126b and covering the second patterned circuit layer 125. The substrate 120 is disposed on the active surface 114 of the chip 110 with its own second surface 126b and the substrate 120 exposes the bonding pads 112 located on the active surface 114. To be more specific, the substrate 120 is disposed on the active surface 114 of the chip 110 with the second solder mask 126 located on the second surface 126b. In addition, the package structure 100 further includes an adhesive 190 disposed between the substrate 120 and the chip 110 for adhering the substrate 120 to the chip 110. In the present embodiment, the size of the chip 110 is greater than the size of the substrate 120 such that the substrate 120 can expose the bonding pads 112 located on the active surface 114 of the chip 110. The wires 130 are connected between the first patterned circuit layer 124 and the bonding pads 112, so as to electrically connect the substrate 120 to the chip 110.

FIG. 2 is a cross-sectional view of a chip package according to another embodiment of the invention. It is noted that the chip package 100 shown in FIG. 2 contains many features same as or similar to the chip package 100 disclosed earlier with FIG. 1. For purpose of clarity and simplicity, detail description of same or similar features may be omitted. Herein, identical or similar elements are indicated with the same or similar reference number. Referring to FIG. 2, the main differences between the chip package 100 shown in FIG. 2 and the chip package 100 shown in FIG. 1 are that, in the present embodiment, the package structure 100 shown in FIG. 2 may further includes a plurality of solder balls 140. The solder balls 140 are disposed on the first surface 126a and electrically connected to the first patterned circuit layer 124. The molding compound 150 covers the chip 110, the wires 130 and the substrate 120 and exposes the solder balls 140, so the package structure 100 may be electrically connected to another electronic device through the solder balls 140. In the present embodiment, the molding compound 150 may be epoxy molding compound. In other words, the material of the molding compound 150 may include epoxy resin, but the invention is not limited thereto.

Referring to FIG. 1 and FIG. 2, the package structure 100 may further include a carrier 160 and an adhesive 170, and the chip 110 is disposed on the carrier 160 with its own back surface 116, and the adhesive 170 is disposed between the chip 110 and the carrier 160 for adhering the chip 110 to the carrier 160. In the present embodiment, the carrier 160 is, for example, a printed circuit board. In other embodiment, however, the carrier 160 may also be a heat sink or a package carrier which can be removed after the molding compound 150 is molded to cover the chips 110, the substrates 120 and the wires 130, so that the overall thickness of the package structure 100 can be further reduced.

In detail, a top surface of the molding compound 150 is coplanar with a top surface of the first solder mask 122, and the thickness T1 of the first solder mask 122 is greater than the loop height h1. To be more specific, the loop height h1 is from a point of one of the wires 130 which is connected to the first patterned circuit layer 124 to a highest point of the one of the wires 130 which is farthest from the active surface 114 as shown in FIG. 1. As such, the top surface of the molding compound 150 is coplanar with the top surface of the first solder mask 122, so the molding compound 150 can cover the entire wires 130. In the present embodiment, the thickness of the first solder mask 122 is greater than the thickness of the second solder mask 123, and the thickness T1 of the first solder mask 122 is greater than, for example, 30 μm. Of course, the invention is not limited thereto. The chips 110 are disposed on the carrier 160 with their own back surfaces 116.

With the disposition described above, the substrate 120 is disposed on the active surface 114 of the chip 110 and exposes the bonding pads 112 of the chip 110. The wire bonding process is performed by forming a stitch bond from the first patterned circuit layer 124 of the substrate 120 down to a bonding pad 112 of the chip 110. Therefore, the highest point of the wire 130 is close to the part of the wire 130 connected to the first patterned circuit layer 122. Accordingly, the thickness T1 of the first solder mask 122 covering the first patterned circuit layer 122 is greater than the loop height h1, so as long as the top surface of the molding compound 150 is coplanar with the top surface of the first solder mask 122, the molding compound 150 is able to cover the entire wire 130, so the loop height h1 of the wire 130 would not give additional thickness to the package structure 100. Therefore, the overall thickness of the package structure 100 can be reduced, so as to meet the of low-profile requirements.

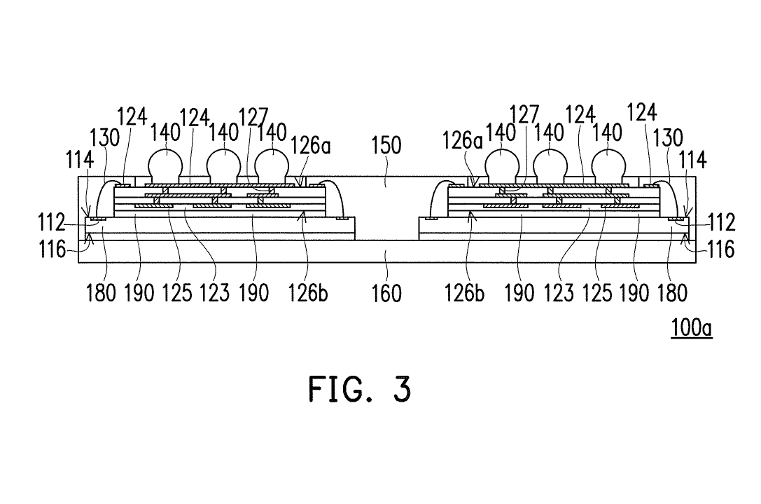

FIG. 3 is a cross-sectional view of a chip package according to another embodiment of the invention. It is noted that the chip package 100a shown in FIG. 3 contains many features same as or similar to the chip package 100 disclosed earlier with FIG. 2. For purpose of clarity and simplicity, detail description of same or similar features may be omitted. Herein, identical or similar elements are indicated with the same or similar reference number. Referring to FIG. 3, the main differences between the chip package 100a shown in FIG. 3 and the chip package 100 shown in FIG. 2 are that, in the present embodiment, the number of the chip 110 is plural, and the number of the substrate 120 is also plural. The substrates 120 are disposed on the active surfaces 114 of the chips 110 respectively, and each of the substrates 120 exposes the bonding pads 112 of the corresponding chip 110. In the present embodiment, the size of each chip 110 is greater than the size of each substrate 120, such that the substrates 120 can expose the bonding pads 112 of the corresponding chips 110. The wires 130 are connected between the first patterned circuit layer 124 of each of the substrates 120 and the bonding pads 112 of the corresponding chip 110 for electrically connecting the substrates 120 and the corresponding chips 110.

Similar to the previous embodiment shown in FIG. 1, a top surface of the molding compound 150 may be coplanar with a top surface of each first solder mask 122, and the thickness of each first solder mask 122 is greater than the loop height of each wire 130 from the first patterned circuit layer 124. As such, the molding compound 150 can cover the wires 130 without giving additional thickness to the package structure 100a.

In the present embodiment, the package structure 100a may also includes a second solder mask 123 disposed on the second surface 126 of the substrate 120. The second solder mask 123 covers the second patterned circuit layer 125, and the chips 110 are disposed on the carrier 160 with their own back surfaces 116. In the present embodiment, the thickness of the first solder mask 122 is greater than the thickness of the second solder mask 123. To be more specific, the thickness of the first solder mask 122 may be greater than, for example, 30 μm. Of course, the invention is not limited thereto. In addition, an adhesive 170 is disposed between the chips 110 and the carrier 160, such that the chips 110 are disposed on and attached to the carrier 160 with their own back surfaces 116. In the present embodiment, the carrier 160 is, for example, a printed circuit board. In other embodiment, however, the carrier 160 may also be a heat sink or a package carrier which can be removed after the molding compound 150 is molded to cover the chips 110, the substrates 120 and the wires 130, so that the overall thickness of the package structure 100a can be further reduced.

In sum, in the package structure of the present invention, the substrate is disposed on the chip and exposes the bonding pads of the chip. The wire is connected from the first patterned circuit layer of the substrate to the bonding pad of the chip. Accordingly, the thickness of the first solder mask covers the first patterned circuit layer is greater than the loop height of the wire from the first patterned circuit layer, and the top surface of the molding compound is coplanar with the top surface of the first solder mask, so the molding compound can cover the entire wire loop without giving additional thickness to the package structure. Therefore, the overall thickness of the package structure can be reduced, so as to meet the requirements of low-profile package structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A package structure, comprising:
at least one chip comprising a plurality of bonding pads, an active surface and a back surface opposite to the active surface, the bonding pads disposed on the active surface;
at least one substrate comprising:
a core layer having a first surface and a second surface opposite to the first surface;
a first patterned circuit layer disposed on the first surface; and
a first solder mask disposed on the first surface and partially exposing the first patterned circuit layer and the substrate disposed on the active surface with the second surface and exposing the bonding pads;
a plurality of wires connected between the first patterned circuit layer and the bonding pads; and
a molding compound covering the chip, the wires and a part of the substrate, wherein a top surface of the molding compound is coplanar with a top surface of the first solder mask.

2. The package structure as claimed in claim 1, further comprising a plurality of solder balls disposed on the first surface and electrically connected to the first patterned circuit layer exposed by the first solder mask.

3. The package structure as claimed in claim 1, further comprising a carrier, wherein the chip is disposed on the carrier with the back surface.

4. The package structure as claimed in claim 3, further comprising an adhesive disposed between the chip and the carrier.

5. The package structure as claimed in claim 1, wherein a loop height is from a point of one of the wires connecting to the first patterned circuit layer to a highest point of the one of the wires farthest from the active surface, and the thickness of the first solder mask is greater than the loop height.

6. The package structure as claimed in claim 1, wherein the thickness of the first solder mask is greater than 30 μm.

7. The package structure as claimed in claim 1, wherein the substrate further comprises a second patterned circuit layer and a plurality of conductive vias, the second patterned circuit layer is disposed on the second surface, and the conductive vias are configured for electrically connecting the first patterned circuit layer and the second patterned circuit layer.

8. The package structure as claimed in claim 7, wherein the substrate further comprises a second solder mask disposed on the second surface of the substrate and covering the second patterned circuit layer, and the substrate is disposed on the active surface with second solder mask.

9. The package structure as claimed in claim 8, wherein a thickness of the first solder mask is greater than a thickness of the second solder mask.

10. The package structure as claimed in claim 1, further comprising an adhesive, disposed between the substrate and the chip.

11. The package structure as claimed in claim 1, wherein a size of the chip is greater than a size of the substrate.

12. The package structure as claimed in claim 1, wherein the number of the at least one chip is plural, the number of the at least one substrate is plural, and each of the substrate disposed on the active surface of the corresponding chip and exposing the corresponding bonding pads.

13. The package structure as claimed in claim 12, wherein the wires are connected between the first patterned circuit layer of each substrate and the bonding pads of the corresponding chip.

14. The package structure as claimed in claim 12, further comprising a carrier, wherein the chips are disposed on the carrier with the back surfaces.

15. The package structure as claimed in claim 12, further comprises an adhesive disposed between the chips and the carrier.
